(19) United States
(12) Patent Application Publication
(10) Pub. No.: US 2024/0361373 A1
(43) Pub. Date: Oct. 31, 2024

(54) EXPECTED-POWER-VALUE ESTIMATION DEVICE AND EXPECTED-POWER-VALUE ESTIMATION METHOD

(71) Applicant: Mitsubishi Electric Corporation, Tokyo (JP)

(72) Inventor: Akira KAKITANI, Tokyo (JP)

(73) Assignee: Mitsubishi Electric Corporation, Tokyo (JP)

(21) Appl. No.: 18/766,776

(22) Filed: Jul. 9, 2024

Related U.S. Application Data
(63) Continuation of application No. PCT/JP2022/008015, filed on Feb. 25, 2022.

(51) Int. Cl. G01R 29/08

(52) U.S. Cl. CPC G01R 29/0892

(57) ABSTRACT

An expected-power-value estimation device is configured to in such a way as to include: a covariance matrix calculation unit that acquires a received signal vector of a reflected wave from a reception array antenna that receives the reflected wave from a target, and calculates a covariance matrix of the received signal vector; and an unnecessary vector value removal unit that removes a vector value present inside a convex hull of the array manifold vector from among a plurality of vector values that the array manifold vector of the reception array antenna can take. Furthermore, the expected-power-value estimation device includes an expected-power-value estimation unit that estimates an expected-power-value of the reflected wave using a vector value that is not removed by the unnecessary vector value removal unit among the plurality of vector values that the array manifold vector can take, and the covariance matrix calculated by the covariance matrix calculation unit.

### CROSS REFERENCE TO RELATED APPLICATION

This application is a Continuation of PCT International Application No. PCT/JP2022/008015, filed on Feb. 25, 2022, which is hereby expressly incorporated by reference into the present application.

### TECHNICAL FIELD

The present disclosure relates to an expected-power-value estimation device and an expected-power-value estimation method.

### BACKGROUND ART

There is an expected-power-value estimation device that estimates an expected-power-value of a reflected wave from a target (see, for example, Non-Patent Literature 1). The expected-power-value is, for example, an average value of measurement values obtained when power values of reflected waves are measured.

The expected-power-value estimation device includes a covariance matrix calculation unit and an expected-power-value estimation unit. The covariance matrix calculation unit acquires a received signal vector of the reflected wave from a reception array antenna that receives the reflected wave from the target, and calculates a covariance matrix of the received signal vector. The expected-power-value estimation unit performs processing of estimating the expected-power-value of the reflected wave using all vector values that an array manifold vector of the reception array antenna can take, and the covariance matrix calculated by the covariance matrix calculation unit.

### CITATION LIST

### Non-Patent Literature

Non-Patent Literature 1: Robert G. Lorenz, Member, IEEE, and Stephen P. Boyd, Fellow, IEEE “Robust Minimum Variance Beamforming”, IEEE transactions on signal processing 53.5 (2005): 1684-1696.

### SUMMARY OF INVENTION

### Technical Problem

A plurality of vector values that the array manifold vector can take may include a vector value that has little influence on an estimation value of the expected-power-value.

In the expected-power-value estimation device disclosed in Non-Patent Literature 1, the expected-power-value estimation unit performs processing of estimating the expected-power-value using not only the vector value that has a significant influence on the estimation value of the expected-power-value, but also all vector values. Therefore, there has been a problem that, when the number of vector values that the array manifold vector can take is larger, a computation load in the processing of estimating the expected-power-value is greater.

The present disclosure has been made to solve the above problem, and an object of the present disclosure is to provide an expected-power-value estimation device and an expected-power-value estimation method that can reduce a computation load in processing of estimating an expected-power-value more than an expected-power-value estimation device disclosed in Non-Patent Literature 1.

### Solution to Problem

An expected-power-value estimation device according to the present disclosure includes: covariance matrix calculation circuitry to acquire a received signal vector of a reflected wave from a reception array antenna to receive the reflected wave from a target, and calculate a covariance matrix of the received signal vector; and unnecessary vector value removal circuitry to remove a vector value present inside a convex hull of an array manifold vector of the reception array antenna from a plurality of vector values that the array manifold vector is capable of taking. Furthermore, the expected-power-value estimation device includes expected-power-value estimation circuitry to estimate an expected-power-value of the reflected wave using a vector value that is not removed by the unnecessary vector value removal circuitry among the plurality of vector values that the array manifold vector is capable of taking, and the covariance matrix calculated by the covariance matrix calculation circuitry.

### Advantageous Effects of Invention

According to the present disclosure, it is possible to reduce a computation load in processing of estimating an expected-power-value more than an expected-power-value estimation device disclosed in Non-Patent Literature 1.

### BRIEF DESCRIPTION OF DRAWINGS

FIG. 1 is a configuration diagram illustrating an expected-power-value estimation device 2 according to Embodiment 1.

FIG. 2 is a hardware configuration diagram illustrating hardware of the expected-power-value estimation device 2 according to Embodiment 1.

FIG. 3 is a configuration diagram illustrating an unnecessary vector value removal unit 12 of the expected-power-value estimation device 2 according to Embodiment 1.

FIG. 4 is a hardware configuration diagram of a computer in a case where the expected-power-value estimation device 2 is implemented by software, firmware, or the like.

FIG. 5 is a flowchart illustrating an expected-power-value estimation method that is a processing procedure of the expected-power-value estimation device 2.

FIG. 6 is an explanatory view illustrating an ellipsoid including a convex hull q(S) of an array manifold vector amv.

### DESCRIPTION OF EMBODIMENTS

Hereinafter, a mode for carrying out the present disclosure will be described with reference to the accompanying drawings to describe the present disclosure in more detail.

### Embodiment 1

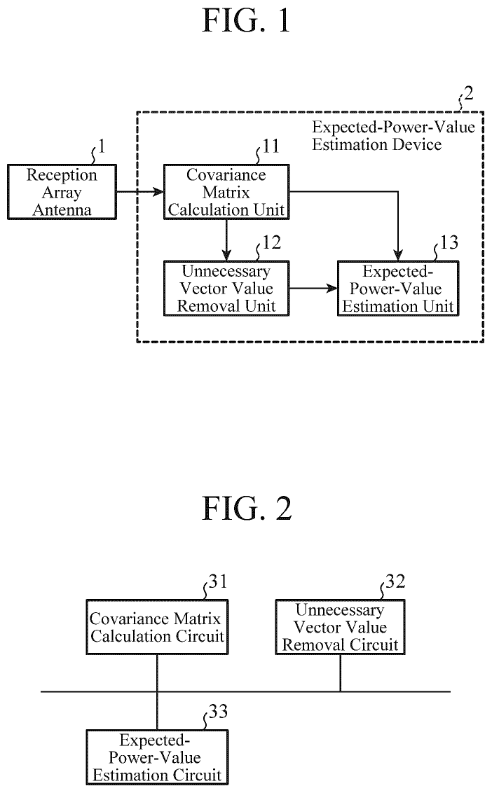

FIG. 1 is a configuration diagram illustrating an expected-power-value estimation device 2 according to Embodiment 1.

FIG. 2 is a hardware configuration diagram illustrating hardware of the expected-power-value estimation device 2 according to Embodiment 1.

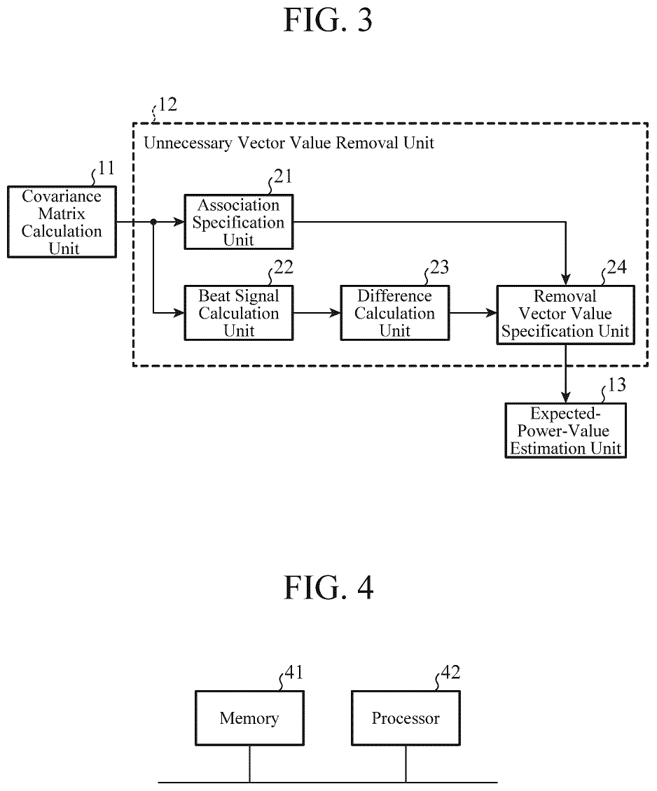

FIG. 3 is a configuration diagram illustrating an unnecessary vector value removal unit 12 of the expected-power-value estimation device 2 according to Embodiment 1.

A reception array antenna 1 includes a plurality of reception antennas.

After a radio wave is transmitted from an unillustrated transmission antenna to a target, the reception array antenna 1 receives a reflected wave that is the radio wave reflected by the target.

The reception array antenna 1 outputs a received signal vector of the reflected wave to the expected-power-value estimation device 2.

In the expected-power-value estimation device 2 illustrated in FIG. 1, the reception array antenna 1 outputs the received signal vector to the expected-power-value estimation device 2. An analog-to-digital converter may be provided between the reception array antenna 1 and the expected-power-value estimation device 2, and the analog-to-digital converter may output a digital signal of the received signal vector to the expected-power-value estimation device 2.

The expected-power-value estimation device 2 illustrated in FIG. 1 includes a covariance matrix calculation unit 11, the unnecessary vector value removal unit 12, and an expected-power-value estimation unit 13.

The expected-power-value estimation device 2 estimates an expected-power-value of the reflected wave by executing the Capon method that uses the received signal vector. The expected-power-value is, for example, an average value of measurement values obtained when power values of reflected waves are measured.

The covariance matrix calculation unit 11 is implemented by, for example, a covariance matrix calculation circuit 31 illustrated in FIG. 2.

The covariance matrix calculation unit 11 acquires a received signal vector from the reception array antenna 1.

The covariance matrix calculation unit 11 calculates a covariance matrix of the received signal vector.

The covariance matrix calculation unit 11 outputs the received signal vector to the unnecessary vector value removal unit 12, and outputs the covariance matrix to the expected-power-value estimation unit 13.

The unnecessary vector value removal unit 12 is implemented by, for example, an unnecessary vector value removal circuit 32 illustrated in FIG. 2.

The unnecessary vector value removal unit 12 includes an association specification unit 21, a beat signal calculation unit 22, a difference calculation unit 23, and a removal vector value specification unit 24.

The unnecessary vector value removal unit 12 removes a vector value that is present inside a convex hull of the array manifold vector from a plurality of vector values that the array manifold vector of the reception array antenna 1 can take.

The association specification unit 21 acquires the received signal vector from the covariance matrix calculation unit 11.

The association specification unit 21 specifies a vector value corresponding to each of a plurality of received signals included in the received signal vector among the plurality of vector values that the array manifold vector can take.

The association specification unit 21 outputs a specification result of the vector value corresponding to each of the received signals to the removal vector value specification unit 24.

The beat signal calculation unit 22 acquires the received signal vector from the covariance matrix calculation unit 11.

The beat signal calculation unit 22 calculates a first beat signal from each of the received signals included in the received signal vector. The first beat signal is a signal calculated without taking a frequency characteristic of a transmission/reception system between the expected-power-value estimation device 2 and the target into account.

The beat signal calculation unit 22 calculates a second beat signal by multiplying each first beat signal with the frequency characteristic of the transmission/reception system. The second beat signal is a signal calculated taking the frequency characteristic of the transmission/reception system between the expected-power-value estimation device 2 and the target into account.

The beat signal calculation unit 22 outputs each first beat signal and the corresponding second beat signal to the difference calculation unit 23.

The difference calculation unit 23 calculates a difference between each first beat signal calculated by the beat signal calculation unit 22, and the second beat signal corresponding to each first beat signal.

The difference calculation unit 23 outputs each difference to the removal vector value specification unit 24.

The removal vector value specification unit 24 acquires the specification result of the vector value corresponding to each of the received signals from the association specification unit 21.

The removal vector value specification unit 24 specifies a vector value corresponding to a received signal related to a difference smaller than a threshold among a plurality of the differences calculated by the difference calculation unit 23 on the basis of the specification results output from the association specification unit 21.

The removal vector value specification unit 24 removes the specified vector value as the vector value that is present inside the convex hull. The threshold may be stored in an internal memory of the removal vector value specification unit 24, or may be given from an outside of the expected-power-value estimation device 2.

The expected-power-value estimation unit 13 is implemented by, for example, an expected-power-value estimation circuit 33 illustrated in FIG. 2.

The expected-power-value estimation unit 13 estimates the expected-power-value of the reflected wave using a vector value that is not removed by the unnecessary vector value removal unit 12 among the plurality of vector values that the array manifold vector can take, and the covariance matrix calculated by the covariance matrix calculation unit 11.

FIG. 1 assumes that each of the covariance matrix calculation unit 11, the unnecessary vector value removal unit 12, and the expected-power-value estimation unit 13 that are the components of the expected-power-value estimation device 2 is implemented by dedicated hardware as illustrated in FIG. 2. That is, it is assumed that the expected-power-value estimation device 2 is implemented by the covariance matrix calculation circuit 31, the unnecessary vector value removal circuit 32, and the expected-power-value estimation circuit 33.

Each of the covariance matrix calculation circuit 31, the unnecessary vector value removal circuit 32, and the expected-power-value estimation circuit 33 corresponds to, for example, a single circuit, a composite circuit, a programmed processor, a parallel-programmed processor, an Application Specific Integrated Circuit (ASIC), a Field-Programmable Gate Array (FPGA), or a combination thereof.

The components of the expected-power-value estimation device 2 are not limited to components that are implemented by the dedicated hardware, and the expected-power-value estimation device 2 may be implemented by software, firmware, or a combination of software and firmware.

The software or the firmware is stored as programs in a memory of a computer. The computer means hardware that executes the programs, and may correspond to, for example, a Central Processing Unit (CPU), a center processing device, a processing device, an arithmetic operation device, a microprocessor, a microcomputer, a processor, or a Digital Signal Processor (DSP).

FIG. 4 is a hardware configuration diagram of the computer in a case where the expected-power-value estimation device 2 is implemented by software, firmware, or the like.

In a case where the expected-power-value estimation device 2 is implemented by the software, the firmware, or the like, programs for causing the computer to execute processing procedures performed in the covariance matrix calculation unit 11, the unnecessary vector value removal unit 12, and the expected-power-value estimation unit 13 are stored in a memory 41. Furthermore, a processor 42 of the computer executes the programs stored in the memory 41.

Furthermore, FIG. 2 illustrates an example where each of the components of the expected-power-value estimation device 2 is implemented by dedicated hardware, and FIG. 4 illustrates an example where the expected-power-value estimation device 2 is implemented by the software, the firmware, or the like. However, these are merely examples, and part of the components of the expected-power-value estimation device 2 may be implemented by the dedicated hardware, and the rest of the components may be implemented by the software, the firmware, or the like.

Next, an operation of the expected-power-value estimation device 2 illustrated in FIG. 1 will be described.

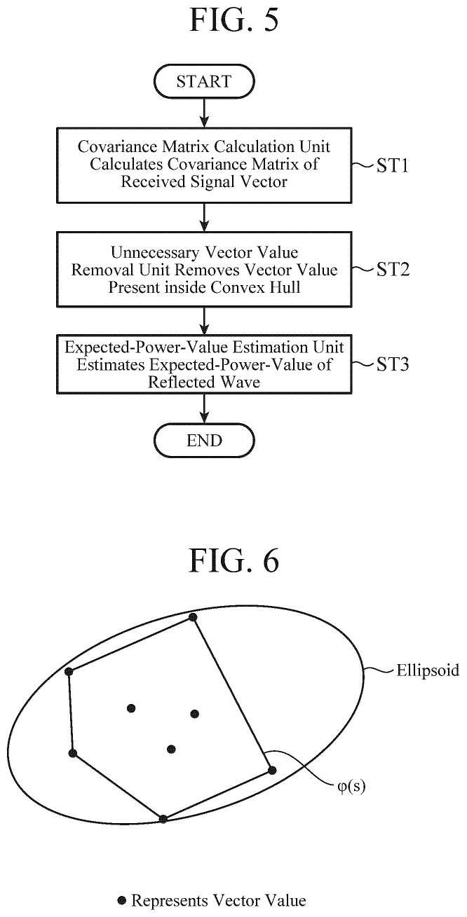

FIG. 5 is a flowchart illustrating an expected-power-value estimation method that is a processing procedure performed in the expected-power-value estimation device 2.

An array manifold vector amv of the reception array antenna 1 includes vector values amvₘ (m=1, . . . , and M) as M elements as expressed in the following equation (1a). M represents an integer equal to or more than two.

That is, in a case where a received signal virtually received at a certain time by each of M reception antennas included in the reception array antenna 1 is amvₘ in a certain scenario, the array manifold vector amv is an M-dimensional vector whose elements are amv₁ to amv_{M} as expressed in the following equation (1). The certain scenario is that, for example, “the target is present at the position of an angle θ”. A set S⊂C^{m} of the vector value amvₘ that the array manifold vector amv can take is known.

In a case where a received signal actually received at a certain time by each of the M reception antennas included in the reception array antenna 1 is rₘ, a received signal vector r is the M-dimensional vector whose elements are r₁ to r_{M} as expressed in the following equation (1b).

$$amv = {[ {amv}_{1} , {amv}_{2} , ... , {amv}_{M} ]}^{T} ∈ {ℂ}^{m} \qquad ( 1 a )$$

$$r = {[ {r}_{1} , {r}_{2} , ... , {r}_{M} ]}^{T} ∈ {ℂ}^{m} \qquad ( 1 b )$$

In the equations (1) and (2), T is a symbol that represents transposition.

A radio wave transmitted from the unillustrated transmission antenna to the target is reflected by the target.

The reflected wave that is a radio wave reflected by the target is received by the reception array antenna 1.

The reception array antenna 1 receives the reflected wave, and outputs the received signal vector r of the reflected wave to the expected-power-value estimation device 2.

The covariance matrix calculation unit 11 acquires the received signal vector r from the reception array antenna 1.

The covariance matrix calculation unit 11 calculates a covariance matrix R_{y} of the received signal vector r (step ST1 in FIG. 5). Since processing of calculating the covariance matrix R_{y} is a known technique, detailed description thereof will be omitted.

The covariance matrix R_{y} is invertible. The covariance matrix R_{y} is an element of a matrix R as expressed in the following equation (2).

The covariance matrix calculation unit 11 outputs the received signal vector r to the unnecessary vector value removal unit 12, and outputs the covariance matrix R_{y} to the expected-power-value estimation unit 13.

$$R := [ \begin{matrix}Re {R}_{y} & - Im {R}_{y} \\ Im {R}_{y} & Re {R}_{y}\end{matrix} ] ∈ {ℝ}^{2 m \times 2 m} \qquad ( 2 )$$

In the equation (2), ReR_{y} represents a real part of the covariance matrix R_{y}, and ImR_{y} represents an imaginary part of the covariance matrix R_{y}. The matrix R is invertible when the covariance matrix R_{y} is invertible.

R^{2m} represents a parameter that defines an ellipsoid on R^{2m}. As illustrated in FIG. 6, the ellipsoid includes a convex hull φ(S) of the array manifold vector amv.

FIG. 6 is an explanatory view illustrating the ellipsoid including the convex hull φ(S) of the array manifold vector amv.

In FIG. 6, • represents the vector value amvₘ that the array manifold vector amv can take.

The convex hull φ(S) is a mapping expressed in the following equation (3). When a range in which a frequency f changes includes a frequency at which a frequency characteristic D(f) of the transmission/reception system to be described later is other than one, vector values that are a plurality of elements included in the convex hull φ(S) include a vector value that is present inside the convex hull φ(S).

$$ϕ : {ℂ}^{m} \to {ℝ}^{2 m} , {[ {amv}_{1} , {amv}_{2} , ... , {amv}_{M} ]}^{T} ↦ {[ Re {amv}_{1} , ... , Re {amv}_{M} , Im {amv}_{1} , ... , Im {amv}_{M} ]}^{T} \qquad ( 3 )$$

The unnecessary vector value removal unit 12 acquires the received signal vector r from the covariance matrix calculation unit 11.

The unnecessary vector value removal unit 12 removes the vector value amvₘ that is present inside the convex hull φ(S) of the array manifold vector amv from among the M vector values amv₁ to amv_{M} that the array manifold vector amv can take (step ST2 in FIG. 5).

The vector value amvₘ that is present inside the convex hull φ(S) is a vector value that has little influence on an estimation value of the expected-power-value. The vector value amvₘ that significantly influences the estimation value of the expected-power-value is present substantially on the outer circumference of the convex hull φ(S).

The unnecessary vector value removal unit 12 outputs the vector value amvₘ left without being removed among the M vector values amv₁ to amv_{M} to the expected-power-value estimation unit 13.

Hereinafter, processing performed in the unnecessary vector value removal unit 12 will be more specifically described.

The association specification unit 21 acquires the received signal vector r from the covariance matrix calculation unit 11.

The association specification unit 21 specifies the vector value amvₘ corresponding to each of a plurality of the received signals rₘ included in the received signal vector r among the M vector values amv₁ to amv_{M} that the array manifold vector amv can take.

The association specification unit 21 outputs a specification result of the vector value amvₘ corresponding to each of the received signals rₘ to the removal vector value specification unit 24.

The beat signal calculation unit 22 acquires a transmission signal Txₘ(t) related to a radio wave transmitted from the transmission antenna to the target. The transmission signal Txₘ(t) is a chirp signal whose frequency changes as time passes as expressed in, for example, the following equations (4) and (5).

Furthermore, the beat signal calculation unit 22 acquires the received signal vector r from the covariance matrix calculation unit 11. The received signal rₘ included in the received signal vector r is represented by a received signal Rx_{m,1}(t) expressed by the following equation (6) or a received signal Rx_{m,2} (t) expressed by the following equation (7).

$${Tx}_{m} ( t ) = exp ( j 2 π f ( t ) t ) \qquad ( 4 )$$

$$f ( t ) = {f}_{0} + \frac{β}{2} t \qquad ( 5 )$$

$${Rx}_{m , 1} ( t ) = exp ( j 2 π {g}_{{f}_{r}} ( t ) t ) \qquad ( 6 )$$

$${Rx}_{m , 2} ( t ) = D ( {g}_{{f}_{r}} ( t ) ) exp ( j 2 π {g}_{{f}_{r}} ( t ) t ) \qquad ( 7 )$$

$${g}_{{f}_{r}} ( t ) = {f}_{0} - {f}_{r} + \frac{β}{2} t \qquad ( 8 )$$

In the equations (4) to (8), f(t) represents the frequency of the transmission signal Txₘ (t) at a time t. g_{fr}(t) represents the frequency of a received signal Rxₘ(t) at the time t.

f₀ represents the frequency at a chirp start time, and β represents a chirp rate.

fᵣ represents a beat frequency corresponding to a linear distance between the expected-power-value estimation device 2 and the target, and D(f) represents a frequency characteristic of the transmission/reception system at the frequency f in the transmission/reception system between the expected-power-value estimation device 2 and the target.

The received signal Rx_{m,1} (t) is a received signal for which the frequency characteristic D(f) of the transmission/reception system is not taken into account. The received signal Rx_{m,2} (t) is a received signal for which the frequency characteristic D(f) of the transmission/reception system is taken into account.

The beat signal calculation unit 22 calculates a first beat signal beatfr_{m, 1} (t) (m=1, . . . , and M) by multiplying the received signal Rx_{m, 1} (t) and the transmission signal Txₘ (t) as expressed in the following equation (9). The first beat signal beatfr_{m, 1} (t) is a beat signal for which the frequency characteristic D(f) of the transmission/reception system is not taken into account.

Furthermore, the beat signal calculation unit 22 calculates a second beat signal beatfr_{m, 2} (t) (m=1, . . . , and M) by multiplying the received signal Rx_{m, 2} (t) and the transmission signal Txₘ (t) as expressed in the following equation (10). The second beat signal beatfr_{m, 2} (t) is a beat signal for which the frequency characteristic D(f) of the transmission/reception system is taken into account.

Here, the beat signal calculation unit 22 multiplies the received signal Rx_{m, 2} (t) and the transmission signal Txₘ (t). However, this is merely an example, and the beat signal calculation unit 22 may calculate the second beat signal beatfr_{m, 2} (t) by multiplying the first beat signal beatfr_{m, 1} (t) with a frequency characteristic D(g_{fr}(t)) of the transmission/reception system.

The beat signal calculation unit 22 outputs each of the first beat signal beatfr_{m, 1} (t) and the second beat signal beatfr_{m, 2} (t) to the difference calculation unit 23.

$${beatfr}_{m , 1} = Tx ( r ) {Rx}_{m , 1}^{*} ( t ) \qquad ( 9 )$$

$${beatfr}_{m , 2} = Tx ( r ) {Rx}_{m , 2}^{*} ( t ) \qquad ( 10 )$$

The difference calculation unit 23 calculates a difference Δeₘ(t)(m=1, . . . , and M) between the first beat signal beatfr_{m, 1} (t) and the second beat signal beatfr_{m, 2} (t) calculated by the beat signal calculation unit 22 as expressed in the equation (11).

$$Δ {e}_{m} ( t ) = \vert {beatfr}_{m , 1} ( t ) - {beatfr}_{m , 2} ( t ) \vert \qquad ( 11 )$$

The difference calculation unit 23 outputs the difference Δeₘ (t) to the removal vector value specification unit 24.

The removal vector value specification unit 24 acquires the specification result of the vector value corresponding to each of the received signals from the association specification unit 21.

The removal vector value specification unit 24 acquires M differences Δe₁(t) to Δeₘ(t) from the difference calculation unit 23.

The removal vector value specification unit 24 specifies the vector value amvₘ corresponding to the received signal rₘ related to the difference Δeₘ(t) smaller than a threshold Th among the M differences Δe₁(t) to Δe_{M}(t) on the basis of the specification results output from the association specification unit 21.

The removal vector value specification unit 24 removes the specified vector value amvₘ as the vector value amvₘ that is present inside the convex hull φ(S).

For example, it is assumed that a difference Δe₃ (t) between a first beat signal beatfr_{3,1} (t) and a second beat signal beatfr_{3,2} (t) calculated from a received signal r₃ corresponding to a vector value amv₃ among the M vector values amv₁ to amv_{M} is smaller than the threshold Th. Furthermore, it is assumed that a difference Δe₅(t) between a first beat signal beatfr_{5,1} (t) and a second beat signal beatfr_{5,2} (t) calculated from a received signal r₅ corresponding to a vector value amv₅ is smaller than the threshold Th. In this case, the removal vector value specification unit 24 removes the vector value amv₃ and the vector value amv₅ from among the M vector values amv₁ to amv_{M}.

The removal vector value specification unit 24 outputs the vector value amvₘ left without being removed among the M vector values amv₁ to amv_{M} to the expected-power-value estimation unit 13.

The expected-power-value estimation unit 13 acquires the covariance matrix R_{y} from the covariance matrix calculation unit 11, and acquires from the removal vector value specification unit 24 the vector value amvₘ left without being removed.

The expected-power-value estimation unit 13 estimates an expected-power-value P of the reflected wave using the vector value amvₘ left without being removed and the covariance matrix R_{y} (step ST3 in FIG. 5).

More specifically, the expected-power-value estimation unit 13 estimates the expected-power-value P of the reflected wave by executing the Capon method that uses the vector value amvₘ left without being removed and the covariance matrix R_{y}.

The Capon method estimates, the expected-power-value P, an optimal value of an optimization problem expressed in the following equation (12). Since processing of estimating the expected-power-value P by executing the Capon method is a known technique, detailed description thereof will be omitted.

$${min}_{w ∈ {ℂ}^{m}} {w}^{H} {R}_{y} w subject to {w}^{H} amv = 1 \qquad ( 12 )$$

In the equation(12), amv∈C^{m} represents an array manifold vector of a scenario of interest, Ry∈C^{m×m} represents a covariance matrix, and w∈C^{m} represents a Capon filter coefficient vector.

Here, the expected-power-value estimation unit 13 estimates the expected-power-value P of the reflected wave by executing the Capon method that uses the vector value amvₘ and the covariance matrix R_{y}. However, this is merely an example, and the expected-power-value estimation unit 13 may estimate the expected-power-value P of the reflected wave by, for example, executing the robust Capon method. Furthermore, the expected-power-value estimation unit 13 may estimate the expected-power-value P of the reflected wave by solving an optimization problem other than the Capon method.

In above Embodiment 1, the expected-power-value estimation device 2 is configured in such a way as to include: the covariance matrix calculation unit 11 that acquires a received signal vector of a reflected wave from the reception array antenna 1 that receives the reflected wave from a target, and calculates a covariance matrix of the received signal vector; and the unnecessary vector value removal unit 12 that removes a vector value present inside a convex hull of the array manifold vector from among a plurality of vector values that the array manifold vector of the reception array antenna 1 can take. Furthermore, the expected-power-value estimation device 2 includes the expected-power-value estimation unit 13 that estimates an expected-power-value of the reflected wave using a vector value that is not removed by the unnecessary vector value removal unit 12 among the plurality of vector values that the array manifold vector can take, and the covariance matrix calculated by the covariance matrix calculation unit 11. Consequently, the expected-power-value estimation unit 13 can reduce a computation load in processing of estimating an expected-power-value more than the expected-power-value estimation device disclosed in Non-Patent Literature 1.

Note that the present disclosure allows modification of any components in the embodiment, or omission of any components in the embodiment.

### INDUSTRIAL APPLICABILITY

The present disclosure is suitable for the expected-power-value estimation device and the expected-power-value estimation method.

### REFERENCE SIGNS LIST

1: reception array antenna, 2: expected-power-value estimation device, 11: covariance matrix calculation unit, 12: unnecessary vector value removal unit, 13: expected-power-value estimation unit, 21: association specification unit, 22: beat signal calculation unit, 23: difference calculation unit, 24: removal vector value specification unit, 31: covariance matrix calculation circuit, 32: unnecessary vector value removal circuit, 33: expected-power-value estimation circuit, 41: memory, 42: processor.

The invention claimed is:

1. An expected-power-value estimation device comprising:
covariance matrix calculation circuitry to acquire a received signal vector of a reflected wave from a reception array antenna to receive the reflected wave from a target, and calculate a covariance matrix of the received signal vector;
unnecessary vector value removal circuitry to remove a vector value present inside a convex hull of an array manifold vector of the reception array antenna from a plurality of vector values that the array manifold vector is capable of taking; and
expected-power-value estimation circuitry to estimate an expected-power-value of the reflected wave using a vector value that is not removed by the unnecessary vector value removal circuitry among the plurality of vector values that the array manifold vector is capable of taking, and the covariance matrix calculated by the covariance matrix calculation circuitry.

2. The expected-power-value estimation device according to claim 1, wherein the unnecessary vector value removal circuitry specifies a vector value corresponding to each of a plurality of received signals included in the received signal vector among the plurality of vector values that the array manifold vector is capable of taking, and output a specification result of the vector value corresponding to each of the received signals,
calculates first beat signals from the respective received signals, and calculate second beat signals by multiplying the respective first beat signals with a frequency characteristic of a transmission/reception system between the expected-power-value estimation device and the target,
calculates a plurality of differences between the respective first beat signals calculated, and the second beat signal corresponding to the respective first beat signals, and
specifies a vector value corresponding to a received signal related to a difference smaller than a threshold among the plurality of differences calculated, on a basis of the specification result output, and remove the specified vector value as the vector value that is present inside the convex hull.

3. The expected-power-value estimation device according to claim 1, wherein the expected-power-value estimation circuitry estimates the expected-power-value of the reflected wave by executing a Capon method that uses the vector value that is not removed by the unnecessary vector value removal circuitry among the plurality of vector values that the array manifold vector is capable of taking, and the covariance matrix calculated by the covariance matrix calculation circuitry.

4. An expected-power-value estimation method comprising:
acquiring a received signal vector of a reflected wave from a reception array antenna to receive the reflected wave from a target, and calculating a covariance matrix of the received signal vector;
removing a vector value present inside a convex hull of an array manifold vector of the reception array antenna from among a plurality of vector values that the array manifold vector is capable of taking; and
estimating an expected-power-value of the reflected wave using a vector value that is not removed among the plurality of vector values that the array manifold vector is capable of taking, and the covariance matrix calculated.
